(19) United States
(12) Patent Application Publication
(10) Pub. No.: US 2010/0212592 A1
(43) Pub. Date: Aug. 26, 2010

(54) VACUUM PROCESSING APPARATUS

(75) Inventor: Yicheng Li, Chiba-ken (CN)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo-To (JP)

(21) Appl. No.: 12/664,808

(22) PCT Filed: Jun. 13, 2008
(86) PCT No.: PCT/JP2008/060833

§ 371 Date: May 12, 2010

(30) Foreign Application Priority Data
Jun. 19, 2007 (JP) 2007-161522

(51) Int. Cl. C23C 16/00; C23C 16/50

(52) U.S. Cl. 118/723 R

(57) ABSTRACT

An annular groove (150) is formed in a lid (3) of a vacuum processing chamber (2) along the periphery of an opening serving as a gas passage. A metal seal (140), having an annular shape (O-ring shape) as a whole and having a double-layered structure, is provided in the groove (150). An annular recess (160) is formed outside the groove (150) in the cover (3) to surround the groove (150). An annular protrusion (170) corresponding to the recess (160) is formed on a flange portion (130), and a fitting mechanism (180) for fitting the protrusion (170) is formed in the recess (160).

### TECHNICAL FIELD

The present invention relates to a vacuum processing apparatus for carrying out predetermined processing of a processing object in a vacuum atmosphere in a vacuum processing chamber.

### BACKGROUND ART

In a semiconductor device manufacturing process, for example, vacuum processing apparatuses have conventionally been used which carry out predetermined processing, such as heating to form a film, of a processing object such as a semiconductor wafer in a vacuum atmosphere in a vacuum processing chamber.

Among such vacuum processing apparatuses is known a plasma processing apparatus which carries out processing, such as film forming processing by CVD, by introducing a predetermined processing gas into a vacuum processing chamber whose interior is kept in a vacuum atmosphere, and introducing microwaves into the vacuum processing chamber to generate a plasma of the processing gas (see Patent Document) 1).

In vacuum processing apparatuses, such as a microwave plasma processing apparatus as described above, a vacuum processing chamber is sometimes formed of a metal material, such as an aluminum alloy. On the other hand, a piping system, etc. for introducing a processing gas into the vacuum processing chamber, in most cases, is formed of a stainless steel. Thus, a vacuum processing apparatus sometimes has a contact area where metal members formed of different materials are in contact with each other via a vacuum sealing member.

In plasma processing apparatuses for forming a metal film, for example, the presence of impurities, such as oxygen, hydrogen, etc. in a processing chamber adversely affects film forming processing, and therefore it is desired that the interior of the processing chamber be brought into high vacuum, e.g. at the level of 10⁻⁶ Pa. If an ordinary resin O-ring is used in such a high vacuum chamber, oxygen, hydrogen, etc. in the external atmosphere will permeate the O-ring and thus be introduced into the vacuum processing chamber. It is therefore common practice to employ a metal seal as a vacuum sealing member.

The use of a metal seal, however, involves the following problem: When a metal seal is used in the above-described contact area between metal members of different materials, such as aluminum alloy and stainless steel, the relative position of the metal members can be displaced, due to a difference in coefficient of thermal expansion between the metal members, upon processing which involves heating. As a consequence, the metal seal is rubbed by the metal members and damaged, causing vacuum leakage.

Patent Document 1: Japanese Patent Laid-Open Publication No. 2006-342386

### DISCLOSURE OF THE INVENTION

The present invention has been made in view of the above circumstances associated with the conventional art. It is therefore an object of the present invention to provide a vacuum processing apparatus which can prevent damage to a metal seal even when it is exposed to a temperature different from room temperature, thereby reducing the possibility of the occurrence of vacuum leakage as compared to the conventional art.

(Solution for the Problem)

The present invention provides a vacuum processing apparatus comprising: a vacuum processing chamber for housing a processing object and carrying out predetermined processing of the processing object in a vacuum atmosphere; and a vacuum processing apparatus constituent member provided to close an opening of the vacuum processing chamber, said member being composed of a material having a different coefficient of thermal expansion from that of the vacuum processing chamber, wherein, in a contact area between the vacuum processing chamber and the vacuum processing apparatus constituent member, said apparatus is provided with: a metal seal for hermetically sealing the contact area, and a fitting mechanism for securing the vacuum processing apparatus constituent member to the vacuum processing chamber so as to prevent positional displacement between the vacuum processing apparatus constituent member and the vacuum processing chamber due to a difference in thermal expansion between them.

In an embodiment of the vacuum processing apparatus of the present invention, the vacuum processing chamber is composed of an aluminum alloy and the vacuum processing apparatus constituent member is composed of stainless steel.

In an embodiment of the vacuum processing apparatus of the present invention, the apparatus further comprises a gas supply mechanism for supplying a predetermined processing gas into the vacuum processing chamber, and a plasma generating mechanism for generating a plasma of the processing gas in the vacuum processing chamber by application of a high-frequency power.

In an embodiment of the vacuum processing apparatus of the present invention, the vacuum processing apparatus constituent member is a gas piping constituent member for introducing the processing gas into the vacuum processing chamber.

In an embodiment of the vacuum processing apparatus of the present invention, the vacuum processing apparatus constituent member is an exhaust section constituent member for exhausting gas from the vacuum processing chamber.

In an embodiment of the vacuum processing apparatus of the present invention, the apparatus further comprises a heating mechanism so that the temperature in the vacuum processing chamber can be set at a temperature higher than room temperature.

In an embodiment of the vacuum processing apparatus of the present invention, the predetermined processing is film forming processing to form a metal film.

### BRIEF DESCRIPTION OF THE DRAWINGS

FIG. 1 is a diagram illustrating the construction of a plasma processing apparatus according to an embodiment of the present invention.

FIG. 2 is a top view of the plasma processing apparatus of FIG. 1.

FIG. 3 is an enlarged vertical sectional view of a main portion of the plasma processing apparatus of FIG. 1.

FIG. 4 is an enlarged vertical sectional view of a main portion of the plasma processing apparatus of FIG. 1.

### BEST MODE FOR CARRYING OUT THE INVENTION

Preferred embodiments of the present invention will now be described in detail with reference to the drawings.

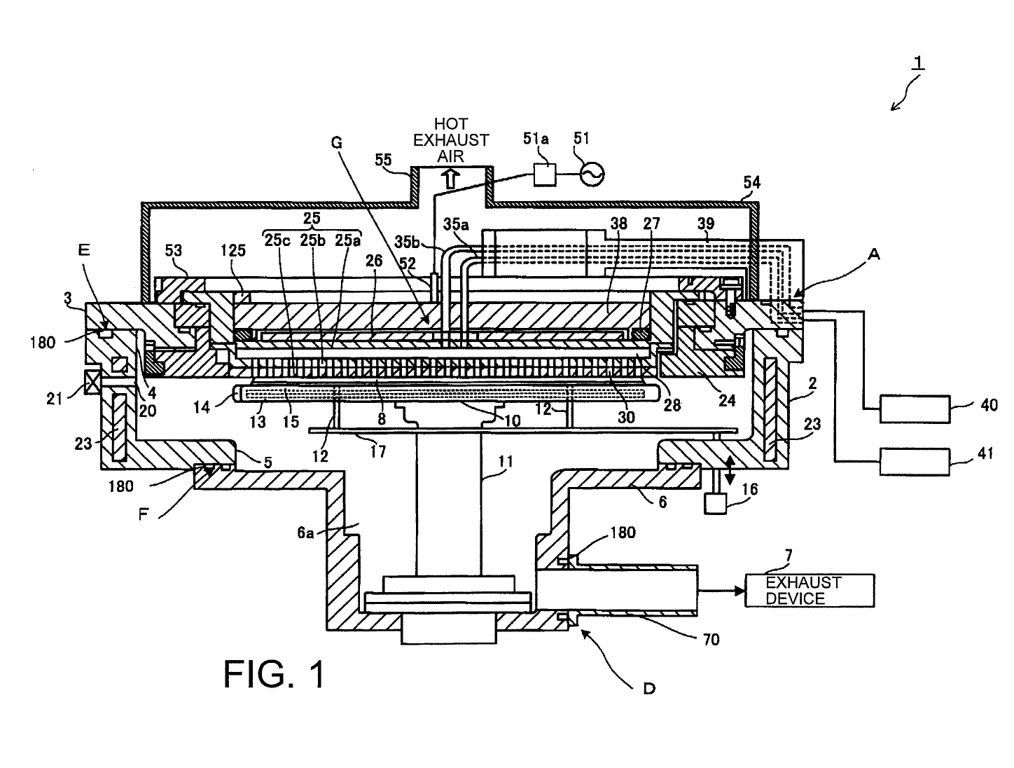

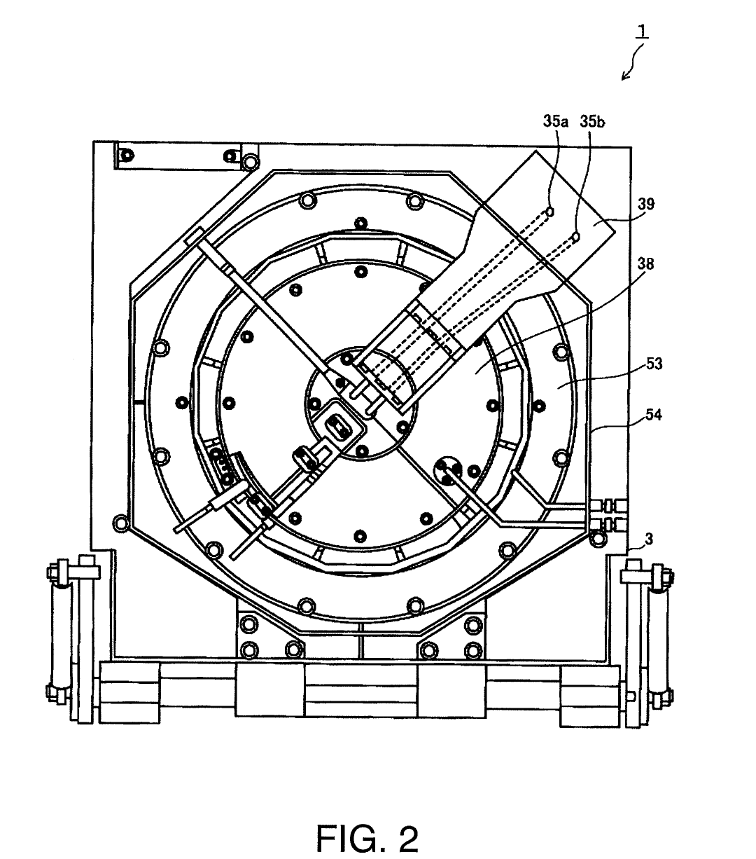

FIGS. 1 and 2 show a vacuum processing apparatus according to the present invention in an embodiment in which the apparatus is constructed as a CVD film forming apparatus. As shown in FIG. 1, the CVD film forming apparatus 1 includes a generally-cylindrical vacuum processing chamber 2 which opens upwardly and downwardly, and a lid 3 and a stage holding member 6 which close a top opening 4 and a bottom opening 5 of the vacuum processing chamber 2, respectively. The stage holding member 6 forms an exhaust chamber 6a in which exhaust gas in the vacuum processing chamber 2 is temporarily collected. Connected to a lower side wall portion of the exhaust chamber 6a is one end of an exhaust pipe 70 as an exhaust section constituent member for evacuating the vacuum processing chamber 2. The other end of the exhaust pipe 70 is connected to an exhaust device 7.

A stage 10 for horizontally placing thereon a semiconductor wafer 8 as a processing object (hereinafter referred to as a processing substrate) is provided in the vacuum processing chamber 2. The stage 10 is installed on a support post 11 which is installed vertically in the exhaust chamber 6a. The state 10 is provided with vertically-movable support pins 12 for supporting the processing substrate 8, a heating means 13 for heating the processing substrate 8, a ring 14 for stabilizing the generation of a plasma, a mesh electrode 15, etc. The support pins 12 are vertically mounted on a support plate 17 which can be moved vertically by a lifting means, such as an air cylinder 16. The upper end portions of the support pins 12 penetrate the stage 10.

In the side wall of the vacuum processing chamber 2 are provided a transfer port 20 for carrying in and out the processing substrate 8, and a gate valve 21 for opening and closing the transfer port 20. In the side wall of the vacuum processing chamber 2 is also provided a built-in cartridge heater 23 for heating the side wall of the vacuum processing chamber 2, so that the temperature of the side wall can be controlled at such a temperature as to prevent condensation of a raw material gas and adhesion of a by-product.

A shower head 25 for discharging a processing gas is mounted via an insulating member 24 to the inner circumference of the lid 3 such that the shower head 25 opposes the stage 10. The shower head 25 includes three circular plates: an upper plate 24a; an intermediate plate 25b; and a lower plate 25c.

The upper plate 25a functions as a base member; and a peripheral portion of the intermediate plate 25b is fixed by screws to the lower surface of a peripheral portion of the upper plate 25a. The upper plate 25a is provided with a disk-shaped inner heater 26 and an annular outer heater 27. The heaters 26, 27 are connected to not-shown power sources, respectively.

The lower plate 25c is in contact with the lower surface of the intermediate plate 25b and is fixed thereto by screws. A hermetic space 28 is formed between the lower surface of the upper plate 25a and the intermediate 25b. A large number of gas flow passages 30 are formed in the intermediate plate 25b and the lower plate 25c such that they penetrate the plates. The gas flow passages 30 are divided into two systems. By supplying two types of gases (first gas and second gas) alternately from the two-system gas flow passages, a thin film of an atomic layer level can be formed by ALD (atomic layer deposition). The shower head 25 is of a post-mixing type that supplies the two-system gases separately. It is, however, possible to use a pre-mixing type shower head that supplies the two-system gases together.

One end of each of a first gas introduction pipe 35a and a second gas introduction pipe 35b for supplying the two types of gases is connected to the upper surface of the upper plate 25a.

The first and second gas introduction pipes 35a, 35b pass through a heat-insulating member 38, embedded in a recess formed in the upper plate 25a and which covers the heaters 26, 27, and through a gas introduction member 39, and are connected at the other ends to gas supply sources 40, 41.

TaCl₅ gas, for example, is supplied as a first gas from the gas supply source 40 and H₂ gas, for example, is supplied as a second gas from the gas supply source 41. By converting these gases into plasma to cause a desired reaction, a Ta film, for example, can be formed on the surface of the processing substrate 8.

The TaCl₅ gas and the H₂ gas, supplied into the vacuum processing chamber 2, are converted into plasma by supplying a high-frequency power from a high-frequency power source 51 via a matching circuit 51a to a power feeding rod 52 connected to the shower head 25, and thereby forming a high-frequency electric field over the processing substrate 8 in the vacuum processing chamber 2, whereby a Ta film-forming reaction is promoted. The shower head 25 is configured to be cooled by supplying dry air thereto upon cooling.

An annular insulating plate 53 for retaining the heat of a top peripheral portion 125 of the shower head 25, and a shield box 54 are provided on the upper surface side of the lid 3. The shield box 54 covers the space over the lid 3 and has, at its top, an exhaust port 55 for exhausting hot air from the dry air supplied to the shower head 25.

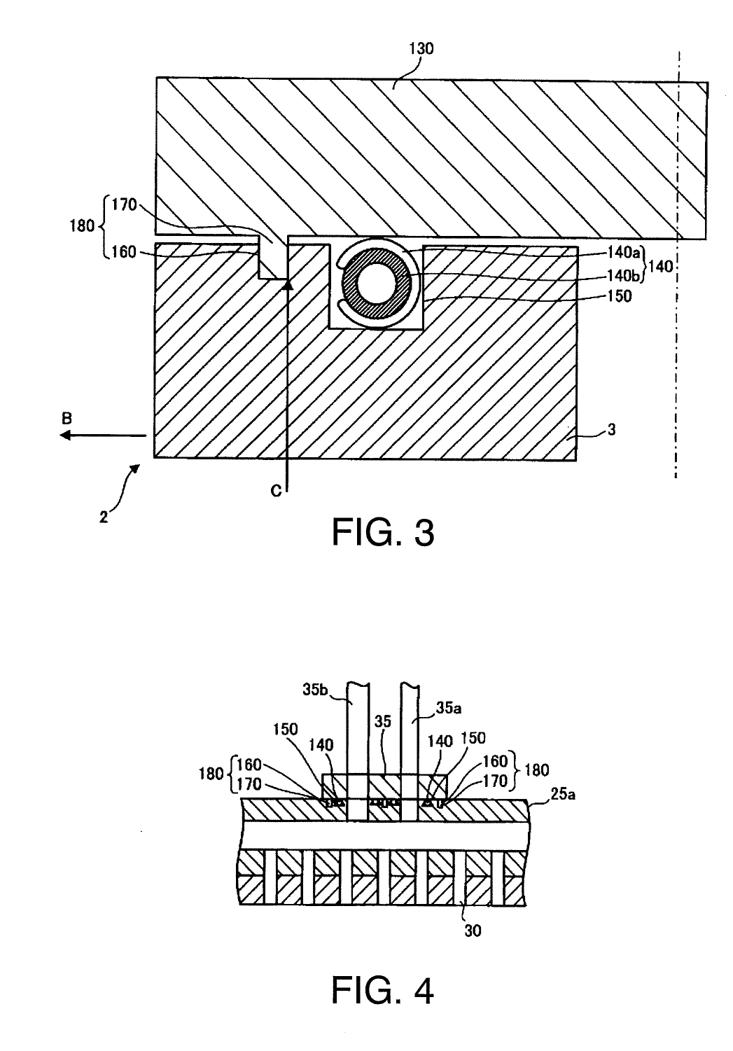

The area shown by arrow A in FIG. 1 is a connection area where connection is formed between gas piping constituent members, i.e. the first gas introduction pipe 35a and the second gas introduction pipe 35b, and gas passages provided in the lid 3 of the vacuum processing chamber 2. As shown in the enlarged view of FIG. 3, a flange portion 130 is provided on the gas piping constituent member side of the connection area A, and connection is made by bringing the flange portion 130 into contact with the lid 3. As with the gas piping constituent members, i.e. the first gas introduction pipe 35a and the second gas introduction pipe 35b, the flange portion 130 is composed of stainless steel. A metal seal 140 as a vacuum sealing member is provided in the contact area between the flange portion 130 and the lid 3. The metal seal 140 has a double structure comprising: a metal O-ring, an inner spiral member 140b having a spring function; and a metal C-ring, an outer member 140a, having the shape of a ring with a cut-off portion, which covers the spiral member 140b. The outer member 140a and the spiral member 140b may be formed of the same material or different materials, such as Inconel (trade name), Hastelloy (trade name), Ni, Al, SUS, etc. Helicoflex Metal (trade name), for example, can be used as the metal seal 140. The metal seal 140 keeps hermetic sealing by utilizing its elasticity and can avoid excessive constriction of the seal. Further, the metal seal 140, owing to recovery of the elasticity, can absorb small distortion of a member due to temperature cycling or pressure cycling.

As shown in FIG. 3, in the lid 3 of the vacuum processing chamber 2, an annular groove 150 is formed around the periphery of an opening serving as a gas flow passage, and the metal seal 140, having an annular overall shape (O-ring shape) is provided in the groove 150. Also in the lid 3 of the vacuum processing chamber 2, an annular recess 160 is formed outside the groove 150 such that it surrounds the groove 150. On the other hand, an annular protrusion 170, corresponding to the recess 160, is formed in the flange portion 130. A fitting mechanism 180 for fitting the protrusion 170 into the recess 160 is thus constructed.

The fitting mechanism 180 is to prevent positional displacement between the flange portion 130 and the lid 3 of the vacuum processing chamber 2, caused by a difference in coefficient of thermal expansion between the stainless steel flange portion 130 and the aluminum alloy lid 3 of the vacuum processing chamber 2 when the temperature of the processing chamber 2 and the lid 3 is raised to a temperature higher than room temperature, e.g. several tens ° C. to 200° C. , thereby preventing the surface of the metal seal 140 from being rubbed and damaged. Even when the processing chamber 2 and the lid 3 are brought to a temperature higher than room temperature, e.g. several tens ° C. to 200° C., upon processing carried out e.g. at a processing temperature of not less than 300° C. , preferably not less than 400° C. , the provision of the fitting mechanism 180 can significantly reduce the possibility of the occurrence of vacuum leakage, caused by damage to the metal seal 140, as compared to the prior art. The upper limit of the processing temperature is 900° C. or lower.

Examples of materials usable for the flange portion 130 include SUS 316(L) (coefficient of thermal expansion 16.0×10⁻⁶/° C.), SUS 303(L) (coefficient of thermal expansion 17.2×10⁻⁶/° C.), SUS 304(L) (coefficient of thermal expansion 17.3×10⁻⁶/° C.), Hastelloy (trade name) (coefficient of thermal expansion 11.5×10⁻⁶/° C.), Inconel (trade name) (coefficient of thermal expansion 11.5×10⁻⁶/° C.). , Ni(coefficient of thermal expansion 13.3×10⁻⁶/° C.), etc. Examples of aluminum alloys usable for the vacuum processing chamber 1 include A5052 (coefficient of thermal expansion 23.8×10⁻⁶/° C.), A5056 (coefficient of thermal expansion 24.3×10⁻⁶/° C.), A5083 (coefficient of thermal expansion 23.4×10⁻⁶/° C.), A6061 (coefficient of thermal expansion 23.6×10⁻⁶/° C.), A6063 (coefficient of thermal expansion 23.4×10⁻⁶/° C.), A7075 (coefficient of thermal expansion 23.6×10⁻⁶/° C.), etc. When such materials are used, the difference in coefficient of thermal expansion will be about 6×10⁻⁶ to 13×10⁻⁶/° C. Accordingly, in the case where the diameter of the flange portion 130 is about 0.1 m, and the temperature is 100° C. raised from room temperature, an elongation difference of about 6×10⁻² to 13×10⁻² mm due to the difference in thermal expansion will be produced in the peripheral portion of the flange portion 130. By reducing such an elongation difference, the surface of the metal seal 140 can be prevented from being rubbed.

Assuming that the center of the flange portion 130 lies in the direction shown by the dash-dot line in FIG. 3, the vacuum processing chamber 2, made of an aluminum alloy having a higher coefficient of thermal expansion, will elongate more by the difference in coefficient of linear expansion in the direction of arrow B shown in FIG. 3. Therefore, the recess 160 and the protrusion 170, on their flange center sides (area shown by arrow C in FIG. 3), come into contact, which suppresses elongation of the chamber 2 (lid 3). It is therefore necessary that the clearance in the area shown by arrow C should be at most 5×10⁻² mm to 50×10⁻² mm at room temperature and preferably, for example, about 10×10⁻² mm to 20×10⁻² mm. In some cases, materials other than the above-described ones, such as Al₂O₃ (coefficient of thermal expansion 6.5×10⁻⁶/° C.), AIN (coefficient of thermal expansion 5.0×10⁻⁶/° C.), etc. are used. The diameter of the groove is not more than 800 mm, preferably not more than 500 mm.

By providing the fitting mechanism 180 at an outer position than the position of the metal seal 140 as shown in FIG. 3, mutual rubbing between the members can be suppressed by the fitting mechanism 180. This can prevent the generation of dust and thus can prevent intrusion of dust into the vacuum processing chamber 2. It is possible to construct a fitting mechanism 18 by providing a protrusion in the lid 3 of the vacuum processing chamber 2 and providing a recess in the flange portion 130. In view of the strengths of the members, however, it is preferred to employ the construction of FIG. 3 in which the protrusion is provided in the flange portion 130 having a higher strength. As shown in FIG. 4, the fitting mechanism 180 having the above construction and the metal seal 140 are provided also in a connection area (area shown by arrow G in FIG. 1) between the gas piping constituent members, i.e. the first gas introduction pipe 35a and the second gas introduction pipe 35b, and the upper plate 25a of the shower head of the vacuum processing chamber 2. In FIG. 4, the first gas introduction pipe 35a and the second gas introduction pipe 35b are connected to a flange 35. It is also possible to provide the metal seal 140 and the protrusion 170 in the flange portion 35 instead of in the upper plate 25a.

The fixing mechanism 180 is provided also in a connection area (area shown by arrow D in FIG. 1) between the above-described stage holding member 6 and the above-described exhaust pipe 70 as an exhaust section constituent member for evacuating the vacuum processing chamber 2.

The fitting mechanism 180, provided in the area shown by arrow D in FIG. 1, is to prevent positional displacement between the stage holding member 6 of aluminum alloy and the exhaust pipe 70 of stainless steel due to a difference in coefficient of thermal expansion between them, thereby preventing the surface of the metal seal 140 from being rubbed and damaged. The fitting mechanism 180 can therefore reduce the possibility of the occurrence of vacuum leakage, caused by damage to the metal seal 140, as compared to the prior art. The fitting mechanism 180 described above can be used in various portions where an opening of the vacuum processing chamber 2 is hermetically closed, for example, a window portion for visualizing the interior of the vacuum processing chamber 2 and an access port portion for access to the interior of the vacuum processing chamber 2 for the purpose of maintenance.

It is conventional practice to seal the connection area between the vacuum processing chamber 2 and the lid 3, shown in FIG. 1 (area shown by arrow E in FIG. 1), with a resin O-ring in order to ensure vacuum sealing between the vacuum processing chamber 2 and the lid 3 while keeping electrical connection therebetween and thus keeping the lid 3 at the ground potential via the vacuum processing chamber 2. However, because of insufficient surface contact between the vacuum processing chamber 2 and the lid 3, the electrical contact resistance between the vacuum processing chamber 2 and the lid 3 is high and a potential difference is produced between them. In contrast, by providing a fitting mechanism 180, having the same construction as that shown in FIG. 3, in the connection area (area shown by arrow E in FIG. 1) between the vacuum processing chamber 2 and the lid 3, low ground potential can be maintained and power can be supplied efficiently without a power loss. This enables the generation of a stable plasma.

The recess and the protrusion of the fitting mechanism 180 make strong contact with each other due to a difference in coefficient of linear expansion between the vacuum processing chamber 2 and the lid 3 when they are formed of different metal materials, or due to a difference in thermal expansion between the vacuum processing chamber 2 and the lid 3, produced by a temperature difference between them, when they are formed of the same metal material. Thus, the provision of the fitting mechanism 180 can reduce the electric resistance between the vacuum processing chamber 2 and the lid 3, thereby keeping the lid 3 at the ground potential via the vacuum processing chamber 2.

The same fitting mechanism 180 is provided also in a connection area (area shown by arrow F in FIG. 1) between the vacuum processing chamber 2 and the stage holding member 6 disposed below it. This can reduce the electric resistance between the vacuum processing chamber 2 and the stage holding member 6, and can thereby keep the vacuum processing chamber 2 and the lid 3 at the ground potential via the stage holding member 6.

As described hereinabove, according to the present invention, even when the wall temperature of the processing chamber 2 becomes a temperature higher than room temperature, e.g. several tens of ° C. to 200° C., upon processing to form a film, the metal seal 140 can be prevented from being damaged, whereby the occurrence of vacuum leakage can be reduced. The seal construction according to the present invention can be applied in any contact area between different materials where vacuum sealing is needed.

The present invention is not limited to the embodiments described above, but various modifications may be made thereto. For example, though the present invention has been described with reference to its application to a plasma CVD apparatus which generates a plasma by means of a high-frequency power, the present invention is also applicable to other vacuum processing apparatuses, such as a microwave plasma CVD apparatus which generates a plasma by means of microwaves.

### INDUSTRIAL APPLICABILITY

The vacuum processing apparatus of the present invention can be advantageously applied, for example, in the field of semiconductor device manufacturing.

1. A vacuum processing apparatus comprising:
a vacuum processing chamber for housing a processing object and carrying out predetermined processing of the processing object in a vacuum atmosphere, the vacuum processing chamber having an opening; and
a vacuum processing apparatus constituent member connected to a part, around the opening, of the vacuum processing chamber, said member being composed of a material having a different coefficient of thermal expansion from that of the vacuum processing chamber,
wherein, in a contact area between the vacuum processing chamber and the vacuum processing apparatus constituent member, said apparatus is provided with:
a metal seal for hermetically sealing the contact area, and
a fitting mechanism provided outside the metal seal to secure the vacuum processing apparatus constituent member to the vacuum processing chamber so as to prevent positional displacement between the vacuum processing apparatus constituent member and the vacuum processing chamber due to a difference in thermal expansion between them.

2. The vacuum processing apparatus according to claim 1, wherein the vacuum processing chamber is composed of an aluminum alloy, and the vacuum processing apparatus constituent member is composed of stainless steel.

3. The vacuum processing apparatus according to claim 1, further comprising:
a gas supply mechanism for supplying a predetermined processing gas into the vacuum processing chamber; and
a plasma generating mechanism for generating a plasma of the processing gas in the vacuum processing chamber by application of a high-frequency power.

4. The vacuum processing apparatus according to claim 1, wherein the vacuum processing apparatus constituent member is a gas piping constituent member for introducing the processing gas into the vacuum processing chamber.

5. The vacuum processing apparatus according to claim 1, wherein the vacuum processing apparatus constituent member is an exhaust section constituent member for exhausting gas from the vacuum processing chamber.

6. The vacuum processing apparatus according to claim 1, further comprising a heating mechanism so that the temperature of the vacuum processing chamber and a lid, which closes an opening of the vacuum processing chamber, can be set at several tens of ° C. to 200° C. .

7. The vacuum processing apparatus according to claim 1, wherein the predetermined processing is film forming processing to form a metal film.

8. The vacuum processing apparatus according to claim 1, wherein the fitting mechanism comprises a protrusion formed on the processing apparatus constituent member side and a recess, into which the protrusion is fitted, formed on the vacuum chamber side.

9. The vacuum processing apparatus according to claim 1, wherein the fitting mechanism comprises a recess formed on the processing apparatus constituent member side and a protrusion formed on the vacuum chamber side and fitted into the recess.

10. The vacuum processing apparatus according to claim 1, wherein the metal seal is composed a first ring portion having an O-shaped cross section and a second ring portion having a C-shaped cross section.

11. The vacuum processing apparatus according to claim 1, wherein the processing object is processed at a processing temperature of 300° C. to 900° C.

12. The vacuum processing apparatus according to claim 1, wherein the opening of the vacuum processing chamber is in fluid communication with an interior space of the vacuum processing chamber.

13. The vacuum processing apparatus according to claim 1, wherein the vacuum processing chamber comprises a cylindrical main body having upper and lower openings, a lid closing the upper opening of the vacuum processing chamber, and a stage holding member closing the lower opening of the vacuum processing chamber.
